(19) United States
(12) Patent Application Publication
(10) Pub. No.: US 2025/0336831 A1
(43) Pub. Date: Oct. 30, 2025

(54) Package with Component Carrier, Interposer and Component and Method of Manufacturing the Same

(71) Applicant: AT&S Austria Technologie & Systemtechnik Aktiengesellschaft, Leoben (AT)

(72) Inventors: Hans PARK, Chongqing (CN); Jeesoo MOK, Leoben (AT)

(21) Appl. No.: 18/880,142

(22) PCT Filed: Jun. 6, 2023
(86) PCT No.: PCT/EP2023/065051

§ 371 Date: Dec. 30, 2024

(30) Foreign Application Priority Data
Jul. 1, 2022 (CN) 202210779311.7

(51) Int. Cl. H01L 23/538; H01L 23/31; H01L 23/498

(52) U.S. Cl. CPC H01L 23/5383; H01L 23/3121; H01L 23/49838

(57) ABSTRACT

A package with a component carrier, an interposer and a component and a method of manufacturing the same. The package includes a component carrier, an interposer arranged on the component carrier having a laminated interposer stack with electrically conductive vertical through connections and electrically conductive horizontal structures in a dielectric matrix, and at least one component arranged on the interposer. At least one of the component carrier and the at least one component is directly connected to exposed horizontal structures of the interposer.

### CROSS REFERENCE TO RELATED APPLICATIONS

This application is a national stage application, filed under 35 U.S.C. § 371, of International Patent Application No. PCT/EP2023/065051, filed on Jun. 6, 2023, claiming priority of Patent Application No. 20221079311.7 filed on Jul. 1, 2022, in China, the disclosures of these patent applications being incorporated by reference herein in their entirety.

### TECHNICAL FIELD

The disclosure relates to a package and to a method of manufacturing a package.

### TECHNOLOGICAL BACKGROUND

In the context of growing product functionalities of component carriers equipped with one or more components and increasing miniaturization of such components as well as a rising number of components to be connected to the component carriers such as printed circuit boards, increasingly more powerful array-like components or packages having several components are being employed, which have a plurality of contacts or connections, with ever smaller spacing between these contacts. In particular, component carriers shall be mechanically robust and electrically reliable so as to be operable even under harsh conditions.

Conventional approaches of forming component carrier-type packages are still challenging.

### SUMMARY

There may be a need to form a compact and reliable component carrier-type package.

According to an exemplary embodiment of the disclosure, a package is provided which comprises a component carrier, an interposer arranged on the component carrier and having a laminated interposer stack comprising electrically conductive vertical through connections and electrically conductive horizontal structures in a dielectric matrix, and at least one component arranged on the interposer, wherein at least one of the component carrier and the at least one component is directly connected to exposed horizontal structures of the interposer.

According to another exemplary embodiment of the disclosure, a method of manufacturing a package is provided, wherein the method comprises forming an interposer with a laminated interposer stack comprising electrically conductive vertical through connections and electrically conductive horizontal structures in a dielectric matrix, arranging the interposer on a component carrier, arranging at least one component on the interposer and directly connecting at least one of the component carrier and the at least one component to exposed horizontal structures of the interposer.

### OVERVIEW OF EMBODIMENTS

In the context of the present application, the term “package” may particularly denote a device having at least one component, in particular electronic component (such as a semiconductor die) mounted on a support structure and being electrically connected in the package.

In the context of the present application, the term “component carrier” may particularly denote any support structure which is capable of accommodating, directly or indirectly, one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In the context of the present application, the term “interposer” may particularly denote a planar electrical interface structure sandwiched between a component carrier and a component and routing electric signals and/or electric energy between component carrier and component. In particular, such an interposer may spread a connection between a wider pitch and a narrower pitch or may re-route a connection to a different connection.

In the context of the present application, the term “stack” may particularly denote an arrangement of multiple planar layer structures which are mounted in parallel on top of one another. In particular, a layer structure may denote a continuous layer, a patterned layer or a plurality of non-consecutive islands within a common plane.

In the context of the present application, the term “vertical through connections” may denote electrically conductive elements connecting different electrically conductive layer structures at different levels of the stack in a vertical direction. The “vertical direction” may be a thickness direction of the package, the component carrier and/or the interposer. Examples of vertical through connections are metallic vias (which may for instance have frustoconical shape, for instance when embodied as metal-filled laser vias, or cylindrical shape, for example when embodied as metal-filled mechanically drilled vias) or metallic pillars (such as copper pillars).

In the context of the present application, the term “horizontal structures” may particularly denote electrically conductive elements extending within, in particular exclusively within, a horizontal plane. Hence, a horizontal structure may be a planar structure defined by any trajectory and/or area within a horizontal plane. For example, such horizontal structures may be pads, traces (in particular wiring structures for signal transmission), trace terminals, etc. For instance, a horizontal structure may interconnect vertical through connections and/or other horizontal structures. In particular, said horizontal structures may be horizontal trace elements and/or horizontal connection elements. In the context of the present application, the term “horizontal trace element” may particularly denote an elongate element of a horizontal electrically conductive layer structure. For instance, such an elongate element may be straight, curved and/or angled. An example of a horizontal trace element is a wiring within a horizontal plane. In the context of the present application, the term “horizontal connection element” may particularly denote a laminar element of an electrically conductive layer structure extending within a horizontal plane. For instance, such a laminar element may be flat or two-dimensional, such as a pad.

In the context of the present application, the term “dielectric matrix” may particularly denote an electrically insulating body with holes which may be filled with metallic material for embedding the horizontal structures and the vertical through connections therein.

In the context of the present application, the term “component” may particularly denote a device or member, for instance fulfilling an electronic and/or a thermal task. For instance, the component may be an electronic component. Such an electronic component may be an active component such as a semiconductor chip comprising a semiconductor material, in particular as a primary or basic material. The semiconductor material may for instance be a type IV semiconductor such as silicon or germanium, or may be a type III-V semiconductor material such as gallium arsenide. In particular, the semiconductor component may be a semiconductor chip such as a naked die or a molded die. At least one integrated circuit element may be monolithically integrated in such a semiconductor chip. However, the component can also be a passive component or another functional body.

In the context of the present application, the term “component carrier and/or component directly connected to exposed horizontal structures of interposer” may particularly denote an electrically conductive and mechanical coupling between a horizontal structure (such as traces and/or pads) and component carrier/component without metallic via or another vertical through connection in between. In particular, the direct connection between horizontal structure (in particular with or without surface finish at a surface thereof) and component carrier/component may be accomplished either with direct physical contact (for instance by thermocompression bonding) or exclusively by an electrically conductive connection medium in between which serves for holding together horizontal structure and component carrier/component. Such an electrically conductive connection medium may be solder, sinter material and/or electrically conductive glue. Preferably, no additional metallic structure may be provided in between said directly connected horizontal structure and the component carrier/component.

According to an exemplary embodiment of the disclosure, a package is provided which is realized as vertical stack of a bottom-sided component carrier, an intermediate laminate-type interposer and a top-sided component. In other words, component and component carrier may be connected at opposing main surfaces of the interposer. Advantageously, component carrier and/or component may be directly connected to exposed horizontal structures of the interposer. Such a direct vertical electric interconnection (and a possibility of a direct horizontal electric interconnection) between interposer and component carrier and/or component using horizontal structures of the interposer for accomplishing such a direct vertical connection, a package may be obtained which is highly compact in vertical direction. In particular, thickening of the package in a vertical direction caused by vertical through connections at an interface between interposer on the one hand and component carrier/component on the other hand may be advantageously avoided. Said direct vertical interconnection may also reliably suppress warpage and may therefore improve the mechanical integrity of the package. These advantages may be synergistically combined with a design allowing for a large mounting surface of the one or more components. This may render it possible for a package designer to freely design even sophisticated electronic applications with a high degree of flexibility.

In the following, further exemplary embodiments of the package and the method will be explained.

In an embodiment, the package comprises a component carrier encapsulant encapsulating at least part of the component carrier. Thus, the component carrier on the bottom side of the package may be encapsulated, in particular by a mold compound. This may ensure compatibility with an increased horizontal extension of the interposer mounted on the encapsulated component. This may lead, in turn, to an increased mounting surface on a top side of the interposer for mounting one or more components, for instance a large die or more than one die. Furthermore, encapsulation of the component carrier may improve the electrical reliability by providing an electrically insulating shell for the component carrier.

In an embodiment, the package comprises a component encapsulant encapsulating at least part of the at least one component. Also, on the top side of the package, a component encapsulant may be provided which may be embodied as a mold compound. This may mechanically protect sensitive components, such as semiconductor chips, and may ensure reliable electric isolation thereof.

In an embodiment, the package comprises at least one further component embedded in the component carrier. Hence, one or more further components may be integrated in an interior of the component carrier. The at least one embedded component may be electrically connected with the at least one component being surface mounted on the interposer by the electrically conductive vertical through connections and/or the electrically conductive horizontal structures of the interposer. The additional provision of an embedded component in the component carrier may allow to increase the electronic functionality of the package without adding excessive volume.

In an embodiment, the horizontal structures are defined by at least one patterned horizontal metal layer, in particular by a plurality of parallel patterned horizontal metal layers. Such horizontal metal layers may be formed based on plated metallic films and/or laminated metal foils. After formation or lamination of such horizontal metal layers, they may be patterned, for example by a lithography and etching process. Preferably, said patterned horizontal metal layers may comprise at least a bottom-sided patterned metal layer providing a direct connection with the component carrier and a top-sided patterned metal layer providing a direct connection with the component. Advantageously, at least one further patterned horizontal metal layer may be arranged in between said bottom-sided and top-sided patterned metal layers, for example for contributing to a redistribution, re-routing or fan-out function.

In an embodiment, at least one of the component carrier and the at least one component is directly connected to the horizontal structures of the interposer without any of the vertical through connections between the component carrier and the horizontal structures and/or between the at least one component and the horizontal structures. In particular, it may be advantageous to accomplish said direct connection without metallic vias and without metallic pillars. In contrast to this, only planar flat horizontal structures may establish said direct electric connection.

In an embodiment, at least one of the component carrier and the at least one component is directly connected to the horizontal structures of the interposer by an electrically conductive connection medium. Said electrically conductive connection medium may comprise for example solder structures, such as solder balls or solder paste. Additionally or alternatively, sinter structures (in particular sinter paste) and/or electrically conductive glue may be used for accomplishing such a direct electric connection. It is also possible that wire bonding and/or the formation of copper pillars and/or bumps may contribute to the direct electric connection. The process of “soldering” may denote a process in which the horizontal structures of the interposer on the one hand and the component carrier and/or the component on the other hand are joined together by melting and putting a filler metal, i.e. solder, into the joint, the filler metal having a lower melting point than the adjoining metal or metals. The process of “sintering” may denote the process of compacting and forming a solid mass of particles by heat and/or pressure without melting it to the point of liquefaction. During sintering, atoms in the particles may diffuse across the boundaries of the particles, fusing the particles together and creating one solid piece.

In an embodiment, the electrically conductive connection medium comprises one or more first electrically conductive connection elements protruding from the component carrier and one or more second electrically conductive connection elements protruding from the interposer and being interconnected with the first electrically conductive connection element. Highly advantageously, two protruding and mutually opposing electrically conductive connection elements (such as solder bumps) contacting each other during formation of the interconnection may ensure a particular reliable electrical and mechanical connection between the interposer on the one hand and the component carrier on the other hand. During connection, said opposing electrically conductive connection elements may become temporarily flowable and may re-solidify after their mutual connection. Preferably, said first and/or second electrically conductive connection element(s) may comprise solder. It is also possible to provide matching arrays of first electrically conductive connection elements protruding from the component carrier and of second electrically conductive connection elements protruding from the interposer.

Generally, the component carrier may be connected to the interposer by one or more electrically conductive connection elements which may also be denoted as metal-to-metal structure. For instance, the component carrier may be connected to the interposer by soldering, a metal-to-metal bond (such as a copper-to-copper bond), sintering and/or electrically conductive glue.

In an embodiment, a lateral extension of the interposer is larger than a lateral extension of the component carrier. The term “lateral direction” may denote a direction that is perpendicular with respect to the stack thickness direction. In other words, the lateral direction may be perpendicular to the z-direction. The lateral direction may be a direction within a horizontal plane. Highly advantageously, an interposer with a large horizontal area may be provided. This may lead to a high mounting surface of the interposer allowing to mount a large-dimensioned component or a plurality of components. By encapsulating the component carrier, the lateral dimensions of the encapsulated component carrier may be matched to the lateral dimensions of the interposer for increasing stability of the package as a whole. Thus, a high component mounting area may be combined with a high mechanical reliability.

In an embodiment, a bottom side of the component carrier comprises at least one exposed or electrically accessible pad. Said at least one exposed pad may allow to mount the package on a mounting base, such as a larger printed circuit board. Furthermore, by such at least one exposed pad on the bottom side of the component carrier, an electric connection between mounting base and package may be established. It is also possible that at least one further component is surface mounted on the bottom side of the package by connecting it electrically with the at least one exposed pad. The mentioned at least one exposed pad may extend beyond a component carrier encapsulant encapsulating part of the component carrier.

In an embodiment, the at least one exposed pad comprises a surface finish. Exposed surface portions of the pad may be covered with a surface finish, such as ENEPIG, OSP or ENIPIG, for suppressing corrosion and oxidation.

In an embodiment, at least part of the horizontal structures being directly connected with the at least one component comprises a surface finish. Avoiding oxidation of connecting surface areas of the horizontal structures by providing them with a surface finish, such as ENEPIG or OSP, may ensure a reliable electric connection in the interior of the package.

In an embodiment, the electrically conductive vertical through connections and the electrically conductive horizontal structures of the interposer form a redistribution structure. In the context of the present application, the term “redistribution structure” may particularly denote an arrangement of interconnected patterned electrically conductive layers which have a portion with a lower pitch as compared to another portion with a higher pitch. Pitch may denote a characteristic distance between adjacent electrically conductive elements, such as trace elements and/or connection elements. By providing upper and lower portions of the interposer with different pitch, a redistribution structure may form an electric interface between larger dimensioned electric connection elements on the component carrier-side and smaller dimensioned electric connection elements on the component-side of the interposer. In particular, a number of electrically conductive elements per area may be smaller in a portion with larger pitch than in another portion with smaller pitch.

In an embodiment, each of the electrically conductive through connections of the interposer is vertically spaced with respect to the at least one component and the component carrier by at least part of the electrically conductive horizontal structures. In the described embodiment, the vertical through connections may be arranged in an interior of the interposer only and may not extend up to opposing main surfaces of the interposer. Said main surfaces may be defined partially by the dielectric matrix and partially by the horizontal structures. The main surfaces may form the two largest surface areas of the interposer. The main surfaces are connected by circumferential side walls. The thickness of an interposer is defined by the distance between the two opposing main surfaces. The main surfaces may comprise functional sections, such as conductive traces or conductive pad-like interconnections or bumps.

In an embodiment, at least one of said exposed horizontal structures extends up to a different vertical level (preferably up to a lower vertical level, i.e. under) compared with another vertical level of a main surface of the interposer with respect to which said at least one exposed horizontal structure is exposed. For example, it is possible that a main surface of the interposer may be defined by the dielectric matrix in which one or more grooves, cavities or recesses may be formed. In said grooves, cavities or recesses, one or more horizontal structures may be arranged and exposed spatially retracted with respect to the dielectric matrix surface. Such an embodiment is shown on the top main surface of the interposer in FIG. 1. By such spatially retracted horizontal structures, an electrically conductive connection medium (such as a solder or sinter structure) may be at least partially accommodated in said grooves, cavities or recesses which improves the reliability of the electric connection.

In an embodiment, the method comprises forming the package on panel level integrally connected with further packages, and separating the package from the further packages at the end of the manufacturing process. This may improve the throughput and may allow to manufacture the packages on an industrial scale.

In an embodiment, the method comprises forming the interposer on a temporary carrier, thereafter connecting the component carrier with the formed interposer, and subsequently detaching the temporary carrier from the connected interposer-component carrier-assembly. For example, such a temporary carrier may be a support body used during the manufacturing process and being removed from the package before completing manufacture thereof. In an embodiment, such a temporary carrier may be a tape (which may be made of a material with determinable shape comprising adhesive properties) or a releasable plate. For example, the base material of such a carrier may be metal, glass, a composite, etc. Such a carrier may include an organic or an inorganic release layer between base material and a thin copper foil. A release strength may be controlled (for instance to a value in a range from 10 gf/cm to 30 gf/cm for detaching) in accordance with PCB manufacturing processability and/or stability.

In an embodiment, the method comprises at least partially encapsulating the component carrier after the attaching of the component carrier to the interposer and before the detaching of the temporary carrier. Thus, the temporary carrier may support constituents of the package before encapsulating the component carrier which, after encapsulation, may then fulfill the function of a stable mechanical support. The temporary carrier may then be removed for reducing the dimensions of the package.

In an embodiment, the method comprises arranging the at least one component on the interposer after the detaching of the temporary carrier. Hence, the component(s) may be assembled to the interposer of the package at the very end of the manufacturing process. By such a chip-last manufacturing process, a high yield may be achieved.

In an embodiment, the method comprises forming, in particular simultaneously, a surface finish, on exposed metallic portions of main surfaces of the component carrier and of the interposer facing away from each other. By covering two opposing main surfaces simultaneously with a surface finish, a proper oxidation and corrosion protection may be achieved with low effort.

In an embodiment, the method comprises at least partially encapsulating the at least one component after arranging the at least one component on the interposer. The manufacturing process may be completed by an overmolding of the one or more surface mounted components for providing mechanical and electrical protection.

In an embodiment of the package, at least part of the vertical through connections of the interposer may taper, for instance when formed using laser drilling. For example, all vertical through holes of the interposer may taper in the same direction (see for example the manufacturing process of FIG. 7). Furthermore, at least part of vertical through connections of the component carrier may taper, for instance when formed using laser drilling. For example, all vertical through holes of the component carrier may taper in the same direction, or different vertical through holes of the component carrier may taper in opposite directions. However, the vertical through connection may be substantially free of a taper (i.e. may be substantially straight) if it is processed by plasma, exposure, excimer laser, etc. When using a plasma, it may be possible to have an opening formed by laser drilling first (wherein the opening may be on a copper layer as a protection layer for plasma etch later on). Then, it may be possible to use plasma for via formation finally. Alternatively, it may be possible to carry out an exposure to form a via on a photoimageable dielectric, or an excimer laser to form a via on an ABF (Ajinomoto Build-up Film) directly. When the interposer and the component carrier are connected on panel level, this may lead to packages in which some or all vertical through connections of the component carrier and some or all vertical through connections of the interposer taper in opposite directions.

In an embodiment, a stack of the interposer or of the component carrier comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular coated with supra-conductive material or conductive polymers, such as graphene or poly(3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

The aspects defined above and further aspects of the disclosure are apparent from the examples of embodiment to be described hereinafter and are explained with reference to these examples of embodiment.

### BRIEF DESCRIPTION OF THE DRAWINGS

FIG. 1 illustrates a cross-sectional view of a package according to an exemplary embodiment of the disclosure.

FIG. 2 illustrates a cross-sectional view of a package according to another exemplary embodiment of the disclosure.

FIG. 3 illustrates a cross-sectional view of a package according to still another exemplary embodiment of the disclosure.

FIG. 4 illustrates a cross-sectional view of a package according to yet another exemplary embodiment of the disclosure.

FIG. 5, FIG. 6, FIG. 7, FIG. 8, FIG. 9, FIG. 10, FIG. 11, FIG. 12, FIG. 13, FIG. 14, and FIG. 15 illustrate cross-sectional views of structures obtained during carrying out a method of manufacturing a package, shown in FIG. 15, according to an exemplary embodiment of the disclosure.

FIG. 16 illustrates a cross-sectional view of a package according to yet another exemplary embodiment of the disclosure.

### DETAILED DESCRIPTION OF EXEMPLARY EMBODIMENTS

The illustrations in the drawings are schematically presented. It is noted that in different figures similar or identical elements are provided with the same reference signs.

Before referring to the drawings, exemplary embodiments will be described in further detail, some basic considerations will be summarized based on which exemplary embodiments of the disclosure have been developed.

According to an exemplary embodiment, a package is provided which comprises a component carrier (such as a PCB or an IC substrate), at least one surface mounted component (preferably one or more semiconductor chips) and a laminated interposer (preferably with integrated redistribution or fan-out functionality) sandwiched between a component carrier and a component. Advantageously, the component carrier and/or the surface mounted component may be directly connected (preferably by soldering) to exposed horizontal structures (such as two-dimensional wiring traces and/or planar connection pads) of the interposer. In a preferred embodiment, the vertical interconnection between the interposer on the one hand and the component carrier/component on the other hand may thus be accomplished without vertical through connections, such as metal vias or pillars. Such a design may ensure a compact configuration of the package in a vertical direction. At the same time, short electrically conductive connection paths may be established in the vertical direction, which may lead to high signal transmission quality and low signal loss.

More specifically, exemplary embodiments provide a package with an embedded trace redistribution layer (RDL) interposer producible by a chip-last package manufacturing method. This may lead to a high yield. The embedded trace RDL interposer may comprise an encapsulation on both sides (preferably realized by respective mold structures). On a bottom side of the interposer, the component carrier (for instance an IC substrate or a PCB, optionally with an embedded component, for instance a semiconductor die) may be molded. On a top side of the interposer, a surface mounted component (for example a semiconductor die) may be molded.

Descriptively speaking, a package according to an exemplary embodiment of the disclosure may be realized as a substrate/interposer/chip package structure. Such a package, preferably with an integrated redistribution structure, may be manufactured by a chip-last type process flow in which the at least one surface mounted component may be assembled at the end of the manufacturing process. This means that the interposer (preferably with the redistribution layer structure) may be formed before the at least one surface mounted component (such as a semiconductor chip) is mounted thereon. This manufacturing architecture makes it possible that the surface mounted semiconductor chips may be verified as “known good” prior to mounting. Consequently, the packages may be formed with high yield.

More specifically, a manufacturing method according to an exemplary embodiment of the disclosure may comprise the process of forming a redistribution layer-type interposer on a temporary carrier. Preferably, said interposer may be an organic RDL interposer with embedded traces. A temporary carrier with an interposer may then be connected to a pre-formed component carrier. Said processes may be carried out on a panel level (in particular by executing PCB processes), and thus very efficiently. After this connection, the temporary carrier may be detached and the obtained structure composed of the component carrier and the interposer may be flipped. Thereafter, the at least one component may be surface mounted on the interposer by executing a chip-last process. A particularly advantageous aspect of the manufactured fan-out package is its high yield. Exemplary embodiments may apply a chip-last process, which leads to said high yield. It may be possible to provide respective molds on both sides of a central redistribution layer-type interposer, so that the obtained fan-out package may have advantageous properties in terms of warpage and reliability.

Advantageously, the package may be manufactured based on simple PCB manufacturing technology and efficiently on a panel level. By the direct connection between horizontal structures on both sides of the interposer (preferably with redistribution structure) it may be possible to test the redistribution structure before surface mounting one or more components (such as dies). Descriptively speaking, a “known good” redistribution structure may thus be used for subsequently surface mounting components, which may lead to a high yield.

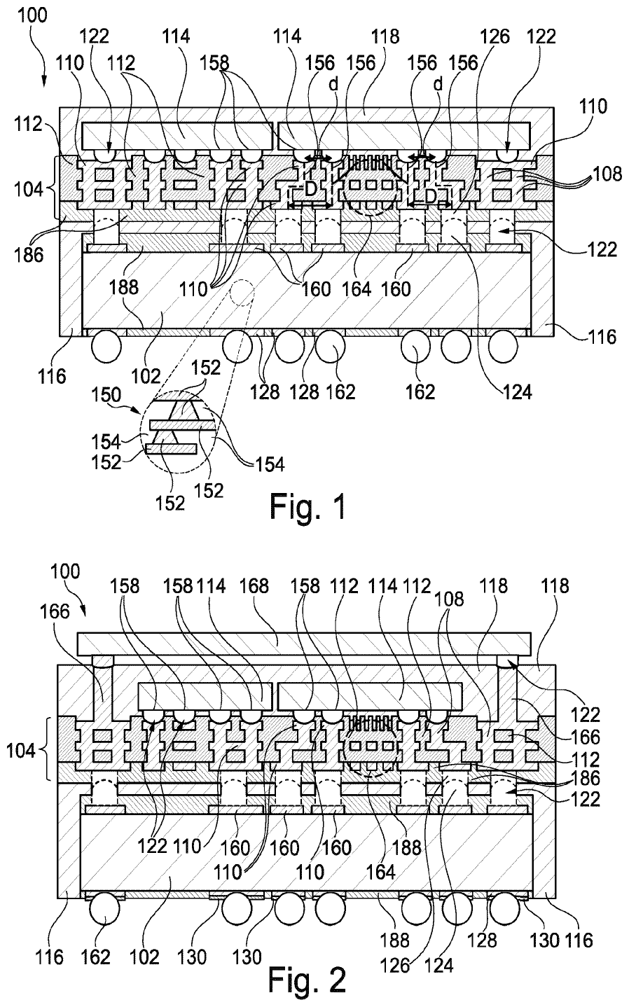

FIG. 1 illustrates a cross-sectional view of a package 100 according to an exemplary embodiment of the disclosure.

The illustrated package 100 is composed of three main constituents, i.e. a component carrier 102, an interposer 104 on the component carrier 102, and surface mounted components 114 on the interposer 104.

More specifically, component carrier 102 can be a plate-shaped laminate-type component carrier, such as a printed circuit board (PCB) or an integrated circuit (IC) substrate. As indicated by a detail 150 in FIG. 1, the component carrier 102 may comprise a laminated layer stack composed of electrically conductive layer structures 152 and one or more electrically insulating layer structures 154. As shown, the electrically conductive layer structures 152 may comprise patterned or continuous copper structures (such as layers or foils). Moreover, the electrically conductive layer structures 152 may further comprise vertical through connections, for example copper filled laser vias which may be created by plating. The one or more electrically insulating layer structures 154 may comprise a respective resin (such as a respective epoxy resin), preferably comprising reinforcing particles therein (for instance glass fibers or glass spheres). For instance, the electrically insulating layer structures 154 may be made of prepreg or FR4.

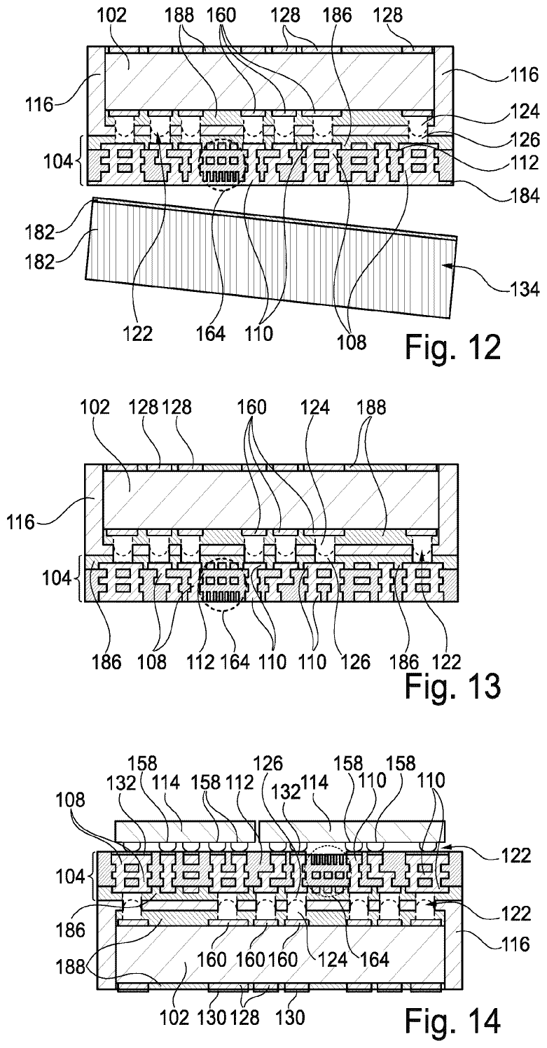

The above-mentioned interposer 104 is arranged on top of the component carrier 102. At an interface between the interposer 104 and the component carrier 102, the interposer 104 may comprise a patterned solder resist 186. Both an upper and a lower main surface of the component carrier 102 may also comprise a patterned solder resist 188. The solder resists 186, 188 in the interior of the package 100 are a fingerprint of the manufacturing process, see FIG. 5 to FIG. 15. As can be taken from FIG. 1, interposer 104 comprises a laminated interposer stack, i.e. a stack of layer structures being interconnected by pressure and/or heat. The illustrated interposer 104 comprises a plurality of electrically conductive vertical through connections 108, which may be in particular copper pillars, copper-filled laser vias (having a frustoconical shape) and/or copper-filled mechanically drilled vias (having a cylindrical shape). Moreover, the interposer 104 comprises electrically conductive horizontal structures 110. The illustrated horizontal structures 110 are defined by parallel patterned horizontal metal layers (for instance patterned copper foils and/or patterned plated copper films). For instance, the electrically conductive horizontal structures 110 may be electrically conductive wiring traces for conducting electrically conductive signals within a horizontal plane and may comprise metallic pads (for instance having a circular shape or rectangular shape). The electrically conductive horizontal structures 104 may be electrically connected with the electrically conductive vertical through connections 108. As shown, the vertical through connections 108 and the horizontal structures 110 are embedded in a dielectric matrix 112. For instance, the dielectric matrix 112 may be made of electrically insulating organic material so that the interposer 104 may be denoted as an organic interposer. Such an organic material may be a dielectric material having an organic compound. In particular, dielectric material of the organic interposer 104 may be made exclusively or at least substantially exclusively from organic material. In another embodiment, the organic interposer 104 may comprise organic dielectric material and additionally another dielectric material. An organic compound may be a chemical compound that contains carbon-hydrogen bonds. For example, the organic interposer 104 may comprise an organic resin material, an epoxy material, etc. In particular, the dielectric matrix 112 may comprise resin or prepreg.

Preferably, the interposer 104 comprises a redistribution structure formed by the illustrated arrangement of the horizontal structures 110 and the vertical through connections 108. Referring to FIG. 1 and as indicated by lines 156, the vertical through connections 108 interconnected with the horizontal structures 110 form a metallic structure inside of interposer 104 which tapers from component carrier 102 towards components 114. Thus, a mutual center-to-center distance, d, between adjacent electrical connections is smaller at the upper main surface of the interposer 104 facing the components 114 compared to a larger mutual center-to-center distance, D, between adjacent electrical connections at the lower main surface of the interposer 104 facing the component carrier 102. Consequently, a higher integration density at said upper main surface may correspond to a smaller line pitch at the electric interface with the components 114. Furthermore, a lower integration density at said lower main surface may correspond to a larger line pitch at the electric interface to the component carrier 102. Thus, the redistribution structure corresponding to reference sign 156 may translate or form an interface between the smaller dimensions of semiconductor technology on the top side and the larger dimensions of component carrier technology on the bottom side of the interposer 104.

As further shown in FIG. 1, two components 114 having the same thickness are surface mounted side by side on the upper main surface of the interposer 104. For example, the components 114 may be semiconductor chips (in particular bare dies or encapsulated dies). For instance, any of the electronic components 114 may be a processor chip, a memory chip, a sensor chip, a logic chip, power chip, RF chip, etc. The electronic components 114 may be coupled with each other by the through connections 108 and horizontal structures 110 of the interposer 104. By taking this measure, the electronic components 114 may functionally cooperate.

Advantageously and as shown in FIG. 1 as well, the component carrier 102 is directly connected to exposed horizontal structures 110 at the lower main surface of the interposer 104 by solder-type electrically conductive connection medium 122 only, i.e. without vertical through connections 108 in between. Alternatively, the electrically conductive connection medium 122 may be a sinter structure or an electrically conductive glue or a solder structure or a metal bump. It is also possible that the electrically conductive connection medium 122 is omitted, for instance when establishing a connection between the component carrier 102 and the bottom-sided exposed horizontal structures 110 by thermocompression bonding or direct metal bonding. In the shown embodiment, the electric connection between the lower main surface of the interposer 104 and pads 160 at a top side of the component carrier 102 may be accomplished exclusively by the bottom-sided exposed horizontal structures 110 and the adhering connection medium 122.

Correspondingly, each of the components 114 is directly connected to exposed horizontal structures 110 at the upper main surface of the interposer 104 by electrically conductive connection medium 122 only, i.e. without vertical through connections 108 in between. More specifically, the electric connection between the upper main surface of the interposer 104 and pads 158 at a bottom side of the components 114 may be accomplished exclusively by the top-sided exposed horizontal structures 110 and the adhering connection medium 122.

Accordingly, each of the electrically conductive through connections 108 of the interposer 104 is vertically spaced with respect to the components 114 and with respect to the component carrier 102 by at least one electrically conductive horizontal structure 110. Thus, vertical through connections 108 are not involved in the formation of the electromechanical connection between interposer 104 on the one hand and component carrier 102 and components 114 on the other hand, neither on the top side nor on the bottom side of the interposer 104. Hence, the component carrier 102 and the components 114 are directly connected to the horizontal structures 110 of the interposer 104 without any of the vertical through connections 108 between the component carrier 102 and the horizontal structures 110 and between the components 114 and the horizontal structures 110. The component carrier 102 and the components 114 are directly connected to the horizontal structures 110 of the interposer 104 by electrically conductive connection medium 122 only, and by no additional structures in between. Advantageously, this leads to a compact design of the package 100 in a vertical direction, since only the flat horizontal structures 110 and not the oblong vertical through connections 108 contribute to said electromechanical connection.

Moreover, package 100 comprises a component carrier encapsulant 116 encapsulating part of the component carrier 102. For instance, component carrier encapsulant 116 may be embodied as a mold compound. Component carrier encapsulant 116 may mechanically protect and electrically isolate the component carrier 102. In addition, component carrier encapsulant 116 may increase the lateral dimensions of the component carrier 102 to match the larger lateral dimensions of the interposer 104, so that the encapsulated component carrier 102 and the interposer 104 have mutually aligned side walls.

Furthermore, package 100 comprises a component encapsulant 118 encapsulating the electronic components 114. For instance, component encapsulant 118 may be embodied as well as a mold compound. Component encapsulant 118 may mechanically protect and electrically isolate the components 114. In addition, component encapsulant 118 may increase the lateral dimensions of the array of surface mounted components 114 to match the larger lateral dimensions of the interposer 104, so that the encapsulated components 114, the encapsulated component carrier 102 and the interposer 104 have mutually aligned side walls (see FIG. 1).

In accordance with the foregoing, the lateral extension of the interposer 104, i.e. the extension of the interposer 104 in the horizontal plane, is larger than a lateral extension of both the component carrier 102 and of the surface mounted components 114. This design advantageously provides a large mounting surface for components 114 to realize even sophisticated electronic functionality in package 100.

In the following, some more specific, but advantageous features of the package 100 according to FIG. 1 will be explained.

As illustrated, the component carrier 102 is directly connected to the horizontal structures 110 of the interposer 104 by a first electrically conductive connection element 124 protruding upwardly from the component carrier 102 and by a second electrically conductive connection element 126 protruding downwardly from the interposer 104. The first electrically conductive connection elements 124 are solder bumps protruding upwardly from pads 160 of the component carrier 102. The second electrically conductive connection elements 126 are further solder bumps protruding downwardly from exposed horizontal structures 110 of the interposer 104. An array of the first electrically conductive connection elements 124 is spatially adapted to an array of the second electrically conductive connection elements 126, as shown in FIG. 1. During manufacture, the array of the first electrically conductive connection elements 124 may be brought in physical contact with the matching array of the second electrically conductive connection elements 126 so that, by applying heat and/or pressure, each pair of a first electrically conductive connection element 124 and an assigned one of the second electrically conductive connection elements 126 may be interconnected. A skilled person will understand that, in the readily manufactures package 100, an interface between a respective first electrically conductive connection element 124 and a respectively connected second electrically conductive connection element 126 may still be visible in a cross-section. The described approach ensures a reliable electric interconnection even in the event of a slight spatial misalignment between interposer 104 and component carrier 102 during manufacture.

FIG. 1 illustrates as well that a bottom side of the component carrier 102 comprises an array of electrically accessible or exposed pads 128, i.e. pads 128 extending beyond the component carrier encapsulant 116. Electrically conductive connection structures 162, such as solder balls, may be applied to each exposed pad 128 for simplifying formation of an electrically conductive connection between the package 100 and a mounting base (not shown, for instance a larger printed circuit board) on which the package 100 may be mounted. More generally, the array of exposed pads 128 may provide a grid array interface. In particular, said grid array interface may be a ball grid array interface or a land grid array interface. Land Grid Array (LGA) and Ball Grid Gray (BGA) are both Surface Mount Technologies (SMT), in particular for printed circuit boards or motherboards. They basically define how the package 100 will actually be mounted, in particular on a PCB or a motherboard's socket. Essentially, the most basic difference between the two is that an LGA based package can be plugged in and out of the PCB or motherboard and can also be replaced. A BGA based package, however, may be soldered on the PCB or motherboard and thus cannot be plugged out or replaced. A Ball Grid Array, on the other hand, may have spherical contacts which are then soldered onto the PCB or motherboard. An LGA type package may be placed on top of a socket on a PCB or motherboard. In this context, the package may have flat surface contacts whereas the PCB or motherboard socket may have pins. FIG. 1 shows a BGA-type grid array interface.

Now referring to the top side of the interposer 104 in FIG. 1, at least some of said exposed horizontal structures 110 extend up to a lower vertical level compared with a higher vertical level of the upper main surface of the interposer 104 with respect to which said exposed horizontal structures 110 are exposed. As can be seen in particular in the uppermost horizontal structures 110 neighbored to the left and right-side walls of the interposer 104, a respective recess is formed between an exposed horizontal surface of the dielectric matrix 112 and the uppermost horizontal structure 110. Electrically conductive connection medium 122 for connecting the components 114 with the exposed horizontal structures 110 of the interposer 104 extends into said recesses in which the respective horizontal structure 110 is exposed. The formation of such recesses simplifies a proper electrical and mechanical connection between interposer 104 and components 114.

In the following, some specific advantages of a package 100 according to exemplary embodiments, such as the one shown in FIG. 1, will be explained: By replacing conventional silicon or glass interposers by the laminate-type organic interposer 104, a redistribution layer may be easily integrated in the interposer 104 using a simple substrate process. By providing the interposer 104 with a whole area size and by embedding traces of the first redistribution layer with a fine line space ratio, it may be possible to advantageously increase the usable die assembly area (thereby increasing the maximum acceptable die size, allowing to increase the number of surface mounted dies or providing the freedom to freely select a die size). Furthermore, the process, equipment and/or material may be much cheaper compared to silicon or glass, so that there will be the advantage of lower manufacturing effort in high volume manufacturing. A particularly preferably design is the provision of an interposer 104 having a larger extension in the horizontal plane than the component carrier 102 which may have, in turn, a larger extension in the horizontal plane than the one or more surface mounted components 114. By manufacturing package 100 using a chip-last concept (see the manufacturing process described below referring to FIG. 5 to FIG. 15), a high yield may be obtained. In such a manufacturing concept, also an easy warpage control may be possible by detaching a temporary carrier only after molding. Furthermore, a package 100 with high reliability may be obtained by double-sided molding, i.e. molding the component carrier 102 on the bottom side and the surface mounted components 114 on the top side. As mentioned above, the component carrier 102 may be configured at its bottom side selectively with a LGA or a BGA interface. Moreover, exemplary embodiments of the disclosure may enable variable package options: For example, copper pillars, underfill, thickness control, etc., may be implemented depending on the requirements of a specific application.

Furthermore, exemplary embodiments of the disclosure may also allow to freely configure different regions of the interposer 104 with different integration density. In this context, the term “integration density” may denote a number of electrically conductive elements (in particular trace elements (such as wiring structures), connection elements (such as pads) and/or vertical through connections (such as metallic vias)) per area or volume of the respective portion. Hence, the amount of electrically conductive elements in a higher density portion may be higher than the amount of electrically conductive elements in a lower density portion. Thus, integration density may mean a quantity of electrically conductive elements per area or volume. The integration density in a lower density portion can be less than in a higher density portion. Correspondingly, the line space ratio and/or line pitch may be higher in a lower density portion than in a higher density portion. The term “line space ratio” may denote a pair of characteristic dimensions of an electrically conductive trace element, i.e. a characteristic line width of one electrically conductive trace element and a characteristic distance between adjacent electrically conductive trace elements. The term “line pitch” may denote a distance between adjacent lines. Since the manufacture of a stack portion with high integration density may involve a larger effort than the manufacture of a stack portion with low integration density, it is advantageous when a high integration density is only manufactured in a region of the stack where needed from a functional point of view. In other portions of the stack in which a low integration density is sufficient for fulfilling a desired function, a simplified manufacturing process can be carried out. With this technology, it can be possible to obtain a target fine line structure and reduce the manufacturing effort at the same time. Just as an example, FIG. 1 illustrates a higher integration density region 164 of the interposer 104 having a higher integration density than other portions of the interposer 104.

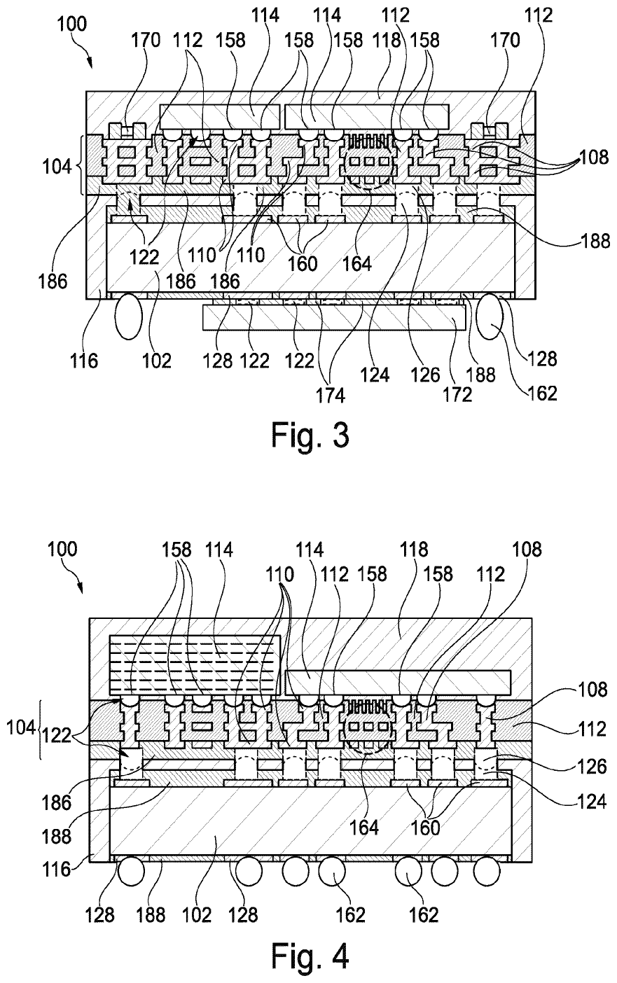

FIG. 2 illustrates a cross-sectional view of a package 100 according to another exemplary embodiment of the disclosure.

The embodiment of FIG. 2 differs from the embodiment of FIG. 1 in particular in that, according to FIG. 2, the exposed pads 128 comprise a surface finish 130. For instance, such a surface finish 130 may be an electrically conductive material (such as OSP or ENEPIG) which inhibits oxidation or corrosion of the pads 128.

Furthermore, the embodiment of FIG. 2 comprises metal pillars 166 (such as copper pillars) extending from an upper main surface of the interposer 104 vertically through the entire component encapsulant 118 and being mechanically and electrically connected with a further component 168 (for example a further semiconductor chip) mounted above the components 114. The electric coupling between the metal pillars 166 and the further component 168 may be accomplished by a further electrically conductive connection medium 122 in between, such as solder. However, it is also possible to provide a direct contact without solder using a pillar protruding from mold material.

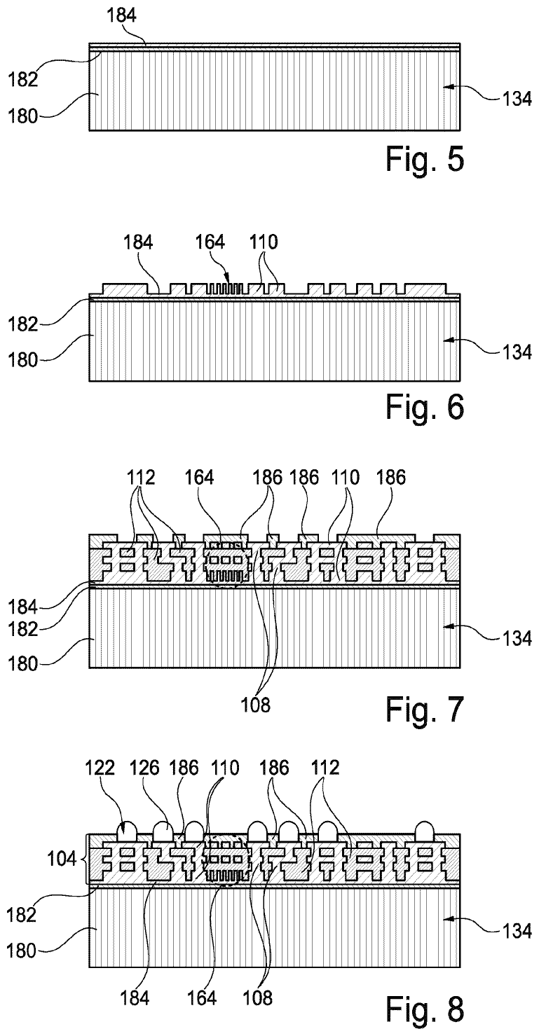

FIG. 3 illustrates a cross-sectional view of a package 100 according to still another exemplary embodiment of the disclosure.

The embodiment of FIG. 3 differs from the embodiment of FIG. 1 in particular in that, according to FIG. 3, additional components 170 may be surface mounted on the interposer 104 and being encapsulated by component encapsulant 118. The additional components 170 are arranged side-by-side with the aforementioned components 114. For instance, the additional components 170 may be passive components (such as an inductor, a capacitance, a power management component, etc.), whereas the aforementioned components 114 may be active components (such as semiconductor chips).

Furthermore, the embodiment of FIG. 3 comprises additionally yet another electronic component 172 being electrically coupled with the exposed pads 128 of the component carrier 102 at the bottom side of package 100. Said electric connection may be accomplished by a further electrically conductive connection medium 122, such as solder. For the purpose of reliably electrically insulating an interface between component carrier 102 and component 172 and for improving mechanical reliability, an electrically insulating underfill 174 may be applied to said interface.

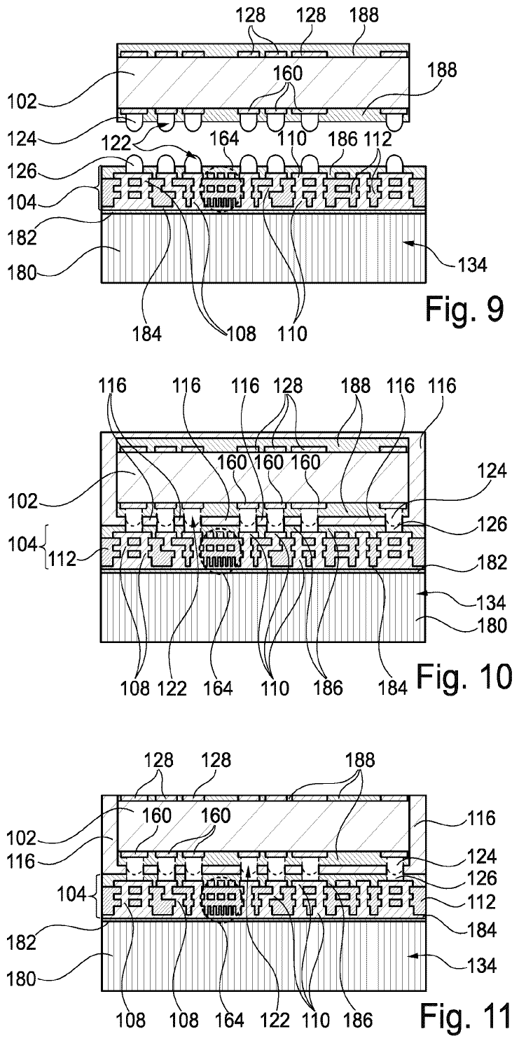

FIG. 4 illustrates a cross-sectional view of a package 100 according to yet another exemplary embodiment of the disclosure.

The embodiment of FIG. 4 differs from the embodiment of FIG. 1 in particular in that, according to FIG. 4, the surface mounted components 114 have different heights (while they have the same height according to FIG. 1).

FIG. 5 to FIG. 15 illustrate cross-sectional views of structures obtained during carrying out a method of manufacturing a package 100, shown in FIG. 15, according to an exemplary embodiment of the disclosure. The illustrated embodiment relates in particular to an embedded trace interposer 104 and a high-yield chip-last package manufacturing method. Advantageously, the package 100 obtained according to FIG. 15 may be manufactured on a panel level, i.e. integrally connected with further packages 100 during the manufacturing process, wherein an individual package 100 may be separated from the further packages 100 only at the end of the manufacturing process. This may enable a high throughput.

Referring to FIG. 5, a starting point of the manufacturing process begins with a temporary carrier 134 for providing temporary support to constituents of the package 100 during subsequent steps of the manufacturing process. For example, temporary carrier 134 may comprise a plate 180 which may be made, for example, from a metal, from glass or from an organic material or other kind of inorganic material. Since the temporary carrier 134 is removed from the package 100 before completing its manufacture, temporary carrier 134 may be provided with a release layer 182 for simplifying its later detachment. Moreover, a metal foil 184 (for example a copper foil) may be arranged on an exterior surface of the temporary carrier 134. Descriptively speaking, metal foil 184 functions as a seed layer during a subsequent metal deposition process.

Referring to FIG. 6, additional metallic material may be applied on the metal foil 184, for instance by galvanically plating. Thereafter, said additional metallic material may be patterned, for instance by a lithography and etching method. The patterned additional metallic material may later form part of a redistribution layer embedded in the manufactured interposer 104.

Referring to FIG. 7, formation of the redistribution layer embedded in the interposer 104 to be manufactured may be continued by creating a further buildup of electrically conductive layer structures (forming vertical through connections 108 and horizontal structures 110) in a dielectric matrix 112. For instance, this may be accomplished by laminating and patterning electrically conductive layer structures (preferably made of copper) and electrically insulating layer structures (for instance resin sheets or prepreg sheets), as well as by drilling holes (mechanically and/or by laser processing) and plating them.

Furthermore, a patterned solder resist 186 may be formed on an upper surface of the formed layer stack, so that electrically conductive connection medium 122 can be formed selectively in openings of the solder resist 186 according to FIG. 8.

Referring to FIG. 8, the uppermost of the electrically conductive horizontal structures 110 may be provided with electrically conductive connection medium 122, which is here embodied as micro bumps. For instance, the electrically conductive connection medium 122 may be solder balls or metal bumps/pillars, so that a solder connection can be established between the electrically conductive horizontal structures 110 and a component carrier 102 (see FIG. 9). More specifically, the electrically conductive connection medium 122 applied according to FIG. 8 may form the electrically conductive connection elements 126 described referring to FIG. 1.

As a result of the described manufacturing process, the illustrated interposer 104 is obtained as a laminated interposer stack. The interposer 104 comprises the electrically conductive vertical through connections 108 interconnected with the electrically conductive horizontal structures 110 and being both embedded in dielectric matrix 112.

Referring to FIG. 9, the interposer 104 and a component carrier 102 are connected with each other. The component carrier 102 may be for example a PCB or an IC substrate and may be covered on both opposing main surfaces thereof with a respective solder resist 188. At the main surface of the component carrier 102 facing the interposer 104, the protruding array of electrically conductive connection elements 124 described above referring to FIG. 1 is provided in alignment with the array of electrically conductive connection elements 126 protruding from the interposer 104. Advantageously, the component carrier 102 is then directly soldered to the exposed horizontal structures 110 of the interposer 104 by the electrically conductive connection elements 124, 126 only, i.e. without involving vertical through connections 108 in said direct connection. This connection process leads to a compact design of the obtained package 100 in vertical direction.

For example, this substrate attach process may be executed on a panel level or on a quarter panel level.

Referring to FIG. 10, the component carrier 102 may be encapsulated by component carrier encapsulant 116 after the connection with the interposer 104. Component carrier encapsulant 116 may be a mold compound formed by molding. For example, said mold-type component carrier encapsulant 116 may be created by a combination of a molded underfill and an overmolding.

Referring to FIG. 11, material of the component carrier encapsulant 116 may be removed for opening or exposing exposed pads 128 of component carrier 102 at an upper main surface thereof. For example, such a pad exposure process may be carried out by grinding.

Referring to FIG. 12, the temporary carrier 134 may then be detached from the interconnected structure composed of interposer 104 and encapsulated component carrier 102.

Referring to FIG. 13, metal foil 184—which is now exposed due to the detachment of the temporary carrier 134 at its release layer 182—may then be removed by copper etching.

Referring to FIG. 14, the structure shown in FIG. 13 is turned upside down.

A surface finish 130, 132 may be formed simultaneously on part of main surfaces of the component carrier 102 and of the interposer 104 facing away from each other. Said surface finish 130, 132 may protect metallic surfaces against oxidation or corrosion.

Furthermore, components 114 are soldered directly on the exposed main surface of the interposer 104. More specifically, exposed electrically conductive horizontal structures 110 of the interposer 104 comprising the surface finish 132 are directly soldered with pads 158 of the components 114 by solder-type electrically conductive connection medium 122.

Referring to FIG. 15, the surface mounted components 114 are subsequently encapsulated by component encapsulant 118 by molding.

Electrically conductive connection structures 162, such as solder balls, may be applied to the surface finish 130 of each exposed pad 128.

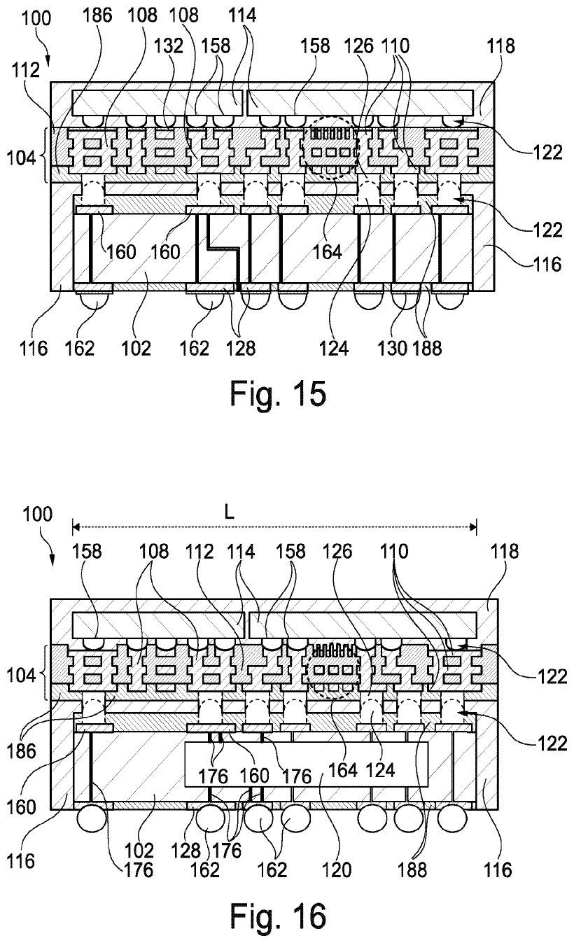

FIG. 16 illustrates a cross-sectional view of a package 100 according to yet another exemplary embodiment of the disclosure.

The embodiment of FIG. 16 differs from the embodiment of FIG. 15 in particular in that, according to FIG. 16, a further component 120 is embedded in the component carrier 102. By electrically conductive connections 176 in component carrier 102, the embedded component 120 may be electrically coupled with surface mounted components 114 and/or an electronic periphery which may be connected to the exposed pads 128.

As shown as well in FIG. 16, a lateral extension, L, over which the surface mounted components 114 extend, may be smaller than a lateral extension of the interposer 104. Hence, the interposer architecture is appropriate for accommodating components 114 over a large range of sizes.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A package, comprising:
a component carrier;
an interposer arranged on the component carrier and having a laminated interposer stack comprising electrically conductive vertical through connections and electrically conductive horizontal structures in a dielectric matrix; and
at least one component arranged on the interposer;
wherein at least one of the component carrier and the at least one component is directly connected to exposed horizontal structures of the interposer.

2. The package according to claim 1, wherein the package comprises a component carrier encapsulant encapsulating at least part of the component carrier.

3. The package according to claim 1, wherein the package comprises a component encapsulant encapsulating at least part of the at least one component.

4. The package according to claim 1, wherein the package comprises at least one further component embedded in the component carrier.

5. The package according to claim 1, wherein the horizontal structures are defined by at least one patterned horizontal metal layer, in particular by a plurality of parallel patterned horizontal metal layers.

6. The package according to claim 1, wherein at least one of the component carrier and the at least one component is directly connected to the horizontal structures of the interposer without any of the electrically conductive vertical through connections between the component carrier and the horizontal structures and/or between the at least one component and the horizontal structures.

7. The package according to claim 1, wherein at least one of the component carrier and the at least one component is directly connected to the horizontal structures of the interposer by an electrically conductive connection medium, in particular only by an electrically conductive connection medium.

8. The package according to claim 7, wherein the electrically conductive connection medium comprises a solder structure, a sinter structure, and/or an electrically conductive glue.

9. The package according to claim 7, wherein the electrically conductive connection medium comprises a first electrically conductive connection element protruding from the component carrier and a second electrically conductive connection element protruding from the interposer and being interconnected with the first electrically conductive connection element.

10. The package according to claim 1, wherein a lateral extension of the interposer is larger than a lateral extension of the component carrier.

11. The package according to claim 1, wherein a bottom side of the component carrier comprises at least one exposed pad.

12. The package according to claim 11, wherein the at least one exposed pad comprises a surface finish.

13. The package according to claim 1, wherein at least part of the horizontal structures being directly connected with the at least one component comprises a surface finish.

14. The package according to claim 1, wherein the electrically conductive vertical through connections and the electrically conductive horizontal structures of the interposer form a redistribution structure.

15. The package according to claim 1, wherein each of the electrically conductive vertical through connections of the interposer is vertically spaced with respect to the at least one component and with respect to the component carrier by at least part of the electrically conductive horizontal structures.

16. The package according to claim 1, wherein at least one of said exposed horizontal structures extends up to a different vertical level compared with another vertical level of a main surface of the interposer with respect to which said at least one exposed horizontal structure is exposed.

17. A method of manufacturing a package, the method comprising:
forming an interposer with a laminated interposer stack comprising electrically conductive vertical through connections and electrically conductive horizontal structures in a dielectric matrix;
arranging the interposer on a component carrier;
arranging at least one component on the interposer; and
directly connecting at least one of the component carrier and the at least one component to exposed horizontal structures of the interposer.

18. The method according to claim 17, wherein the method comprises forming the package on panel level integrally connected with further packages, and separating the package from the further packages at the end of the manufacturing process.

19. The method according to claim 17, wherein the method comprises forming the interposer on a temporary carrier, thereafter attaching the component carrier to the formed interposer, and subsequently detaching the temporary carrier.

20. The method according to claim 17, comprising at least one of the following features:
wherein the method comprises at least partially encapsulating the component carrier after the attaching and before the detaching;
arranging the at least one component on the interposer after the detaching;
simultaneously forming a surface finish on parts of main surfaces of the component carrier and of the interposer facing away from each other;
at least partially encapsulating the at least one component after arranging the at least one component on the interposer.

21.-23. (canceled)
